(19) United States
(12) Patent Application Publication
(10) Pub. No.: US 2012/0211069 A1
(43) Pub. Date: Aug. 23, 2012

(54) THIN-FILM SOLAR CELLS AND METHODS OF FABRICATING THE SAME

(75) Inventors: Sun Jin YUN, Daejeon (KR); JungWook Lim, Daejeon (KR)

(73) Assignee: ELECTRONICS AND TELECOMMUNICATIONS RESEARCH INSTITUTE, Daejeon (KR)

(21) Appl. No.: 13/402,854

(22) Filed: Feb. 22, 2012

(30) Foreign Application Priority Data
Feb. 23, 2011 (KR) 10-2011-0016090
Dec. 16, 2011 (KR) 10-2011-0136575

(51) Int. Cl. H01L 31/0352; H01L 31/0687; H01L 31/0376

(52) U.S. Cl. 136/255; 438/87; 257/E31.047

(57) ABSTRACT

Provided are thin-film solar cells and methods of fabricating the same. The solar cell may include a substrate and a cell comprising an amorphous layer with a continuously graded hydrogen content disposed on the substrate, a n-type semiconductor, an p-type semiconductor layer, a metal electrode adjacent to the n-type semiconductor and a transparent electrode adjacent to p-type semiconductor layers. The hydrogen content of the amorphous intrinsic semiconductor layer decreases in a continuous manner from a first interface, to which a light is incident, toward a second interface opposite to the first interface, and the first and second interfaces are two opposite surfaces of the amorphous intrinsic semiconductor layer being in contact with the p-type and n-type semiconductor layers, respectively.

### CROSS-REFERENCE TO RELATED APPLICATIONS

This U.S. non-provisional patent application claims priority under 35 U.S.C. §119 to Korean Patent Application No. 10-2011-0016090, filed on Feb. 23, 2011 and Korean Patent Application No. 10-2011-0136575, filed on Dec. 16, 2011, the entire contents of which are hereby incorporated by reference.

### BACKGROUND OF THE INVENTION

Embodiments of the inventive concepts relate to thin-film solar cells converting light into electricity and a method of fabricating the same.

A solar light can be converted into electricity by a solar cell. The solar cell is advantageous in that the sun is a substantially infinite energy source and harm elements are not generated. Accordingly, a solar power is an eco-friendly future energy source, which is expected to be able to replace the fossil fuel. However, the solar cell suffers from low energy conversion efficiency, which is one of barriers preventing a rapid increase of market share and productions of the solar cell. Thus, intensive researches have been carried out to improve energy conversion efficiency of the solar cell.

### SUMMARY

Embodiments of the inventive concepts provide solar cells with improved energy conversion efficiency and methods of fabricating the same.

Other embodiments of the inventive concepts provide solar cells, which can be fabricated without using an additional process or apparatus, and methods for fabricating the same.

Still other embodiments of the inventive concepts provide thin-film solar cells, in which at least one amorphous intrinsic semiconductor layer having a high optical absorption coefficient is provided to prevent optical deterioration, and methods of fabricating the same.

According to example embodiments of the inventive concept, a thin-film solar cell may be configured to have a single-junction or multiple-junction cell, in which an intrinsic semiconductor layer with continuously varying properties is provided. The thin-film solar cell may include a cell, in which an intrinsic semiconductor layer capable of absorbing a visible light is provided. The cell with the intrinsic semiconductor layer can be realized without using an additional process or apparatus. In example embodiments, the thin-film solar cell may be configured to include an amorphous intrinsic semiconductor layer having a high optical absorption coefficient.

According to example embodiments of the inventive concept, a thin-film solar cell may include a substrate, and a cell comprising an amorphous layer disposed on the substrate. The amorphous layer may include an intrinsic semiconductor with continuously graded hydrogen content. The amorphous layer may have an incident surface, to which a light is incident, and an opposite surface, and the hydrogen content may decrease in a continuous manner from the incident surface toward the opposite surface.

In example embodiments, the substrate may include a transparent substrate disposed adjacent to the incident surface, and the hydrogen content may decrease in a continuous manner with increasing a distance from the transparent substrate.

In example embodiments, the cell may include a p-type semiconductor layer disposed on the transparent substrate, the amorphous layer having the continuously graded hydrogen content disposed on the p-type semiconductor layer, and an n-type semiconductor layer disposed on the amorphous layer. The hydrogen content may decrease in a continuous manner from a first interface between the amorphous layer and the p-type semiconductor layer toward a second interface between the amorphous layer and the n-type semiconductor layer.

In example embodiments, the solar cell may further include a transparent electrode disposed between the transparent substrate and the cell composed of p-, i-, n-semiconductor, and a metal electrode disposed on the cell.

In example embodiments, the solar cell may further include a reflection layer interposed between the cell and the metal electrode.

In example embodiments, instead of the transparent substrate, the substrate may include an opaque substrate disposed adjacent to the opposite surface, and the hydrogen content may decrease in a continuous manner with decreasing a distance from the opaque substrate.

In example embodiments, the cell may include an n-type semiconductor layer disposed on the opaque substrate, the amorphous layer having the continuously graded hydrogen content disposed on the n-type semiconductor layer, and a p-type semiconductor layer disposed on the amorphous layer. The hydrogen content may decrease in a continuous manner from a first interface between the amorphous layer and the p-type semiconductor layer toward a second interface between the amorphous layer and the n-type semiconductor layer.

In example embodiments, the solar cell may further include a metal electrode disposed between the opaque substrate and the cell, and a transparent electrode disposed on the cell to allow the light to be incident thereto.

In example embodiments, the solar cell may further include a reflection layer interposed between the cell and the metal electrode.

In example embodiments, a bandgap energy and a light absorption coefficient of the amorphous layer may decrease in a continuous manner from the light-incident surface toward the opposite surface, and a density of the amorphous layer may increase in a continuous manner from the light-incident surface toward the opposite surface.

In example embodiments, the amorphous layer may include one of Si, SiGe, SiC, SiO, SiN, SiON, SiCN, SiGeO, SiGeN, SiGeC and any combination thereof.

According to example embodiments of the inventive concept, a thin-film solar cell may include a substrate, a first cell disposed on the substrate, the first cell including a first n-type semiconductor layer, a first p-type semiconductor layer, and a first amorphous layer comprising intrinsic semiconductor with a continuously graded hydrogen content interposed between the first n-type semiconductor layer and the first p-type semiconductor layer, a metal electrode adjacent to the first n-type semiconductor layer, and a transparent electrode adjacent to the first p-type semiconductor layer. The hydrogen content of the first amorphous layer may decrease in a continuous manner from a first interface, to which a light is incident, toward a second interface opposite to the first interface, and the first and second interfaces may be two opposite surfaces of the first amorphous layer being in contact with the first p-type semiconductor layer and the first n-type semiconductor layer, respectively.

In example embodiments, the substrate may include a transparent substrate, to which a light is incident, and the transparent electrode, the first p-type semiconductor layer, the first amorphous layer, the first n-type semiconductor layer, and the metal electrode may be sequentially stacked on the transparent substrate.

In example embodiments, the solar cell may further include at least one second cell interposed between the first cell and the metal electrode. The second cell may include a second p-type semiconductor layer, a second intrinsic semiconductor layer with a continuously graded hydrogen content, and a second n-type semiconductor layer sequentially stacked on the first n-type semiconductor layer. The second intrinsic semiconductor layer may include at least one of an intrinsic amorphous silicon layer and an intrinsic crystalline silicon layer, and the hydrogen content of the second intrinsic semiconductor layer may decrease in a continuous manner with increasing a distance from the transparent substrate.

In example embodiments, the solar cell may further include a back-side reflection layer interposed between the second cell and the metal electrode.

In example embodiments, the substrate may include an opaque substrate, and the metal electrode, the first n-type semiconductor layer, the first amorphous layer, the first p-type semiconductor layer, and the transparent electrode may be sequentially stacked on the opaque substrate. A light may be incident to the solar cell through the transparent electrode.

In example embodiments, the solar cell may further include at least one second cell interposed between the first cell and the metal electrode. The second cell may include a second n-type semiconductor layer, a second intrinsic semiconductor layer with a continuously graded hydrogen content, and a second p-type semiconductor layer sequentially stacked on the metal electrode. The second intrinsic semiconductor layer may include at least one of an intrinsic amorphous silicon layer, an intrinsic microcrystalline silicon layer and an intrinsic crystalline silicon layer, and the hydrogen content of the second intrinsic semiconductor layer may decrease in a continuous manner with decreasing a distance from the opaque substrate.

In example embodiments, the solar cell may further include a back-side reflection layer interposed between the first cell and the metal electrode.

In example embodiments, the first amorphous layer may comprise one of Si, SiGe, SiC, SiO, SiN, SiON, SiCN, SiGeO, SiGeN, SiGeC and any combination thereof.

According to example embodiments of the inventive concept, a method of fabricating a thin-film solar cell may include providing a substrate, forming an cell including a p-type semiconductor layer disposed on the substrate, an n-type semiconductor layer, and an amorphous layer including an intrinsic semiconductor layer with a continuously graded hydrogen content interposed between the p-type and n-type semiconductor layers; forming a transparent electrode adjacent to the p-type semiconductor layer, and forming a metal electrode adjacent to the n-type semiconductor layer. The amorphous layer may have an light-incident surface, to which a light is incident, and an opposite surface, and the hydrogen content may decrease in a continuous manner from the light-incident surface toward the opposite surface.

In example embodiments, the amorphous layer may include one of Si, SiGe, SiC, SiO, SiN, SiON, SiCN, SiGeO, SiGeN, SiGeC and any combination thereof.

In example embodiments, the substrate may include a transparent substrate disposed adjacent to the light-incident surface. The forming of the cell may include forming the p-type semiconductor layer on the transparent substrate; forming the amorphous layer on the p-type semiconductor layer by supplying using a gas mixture of a semiconductor precursor gas diluted with hydrogen gas, a hydrogen dilution ratio being gradually increased as the forming of the amorphous layer advances; and forming the n-type semiconductor layer on the amorphous layer.

In example embodiments, the substrate may include an opaque substrate disposed adjacent to the opposite surface. The forming of the cell may include forming the n-type semiconductor layer on the opaque substrate; forming the amorphous layer on the n-type semiconductor layer by supplying using a gas mixture of a semiconductor precursor source gas diluted with hydrogen gas, a hydrogen dilution ratio being gradually decreased as the forming of the amorphous layer advances; and forming the p-type semiconductor layer on the amorphous layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a sectional view of a thin-film solar cell according to example embodiments of the inventive concept;

FIG. 1B is a flow chart illustrating a method of fabricating a thin-film solar cell according to example embodiments of the inventive concept;

FIG. 1C is a sectional view illustrating a cell of a thin-film solar cell according to example embodiments of the inventive concept;

FIG. 1D is a sectional view illustrating an operating principle of a thin-film solar cell according to example embodiments of the inventive concept;

FIGS. 1E through 1G are sectional views of thin-film solar cells according to other example embodiments of the inventive concept;

FIG. 2A is a sectional view of a thin-film solar cell according to modified embodiments of the inventive concept;

FIG. 2B is a flow chart illustrating a method of fabricating a thin-film solar cell according to modified embodiments of the inventive concept;

FIG. 2C is a sectional view illustrating a cell of a thin-film solar cell according to modified embodiments of the inventive concept;

FIG. 2D is a sectional view illustrating an operating principle of a thin-film solar cell according to modified embodiments of the inventive concept; and

FIGS. 2E through 2G are sectional views of thin-film solar cells according to still other example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

### Embodiment 1

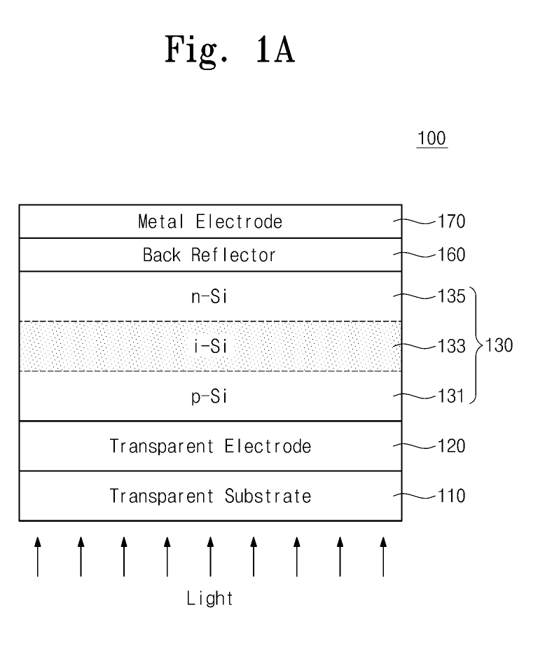

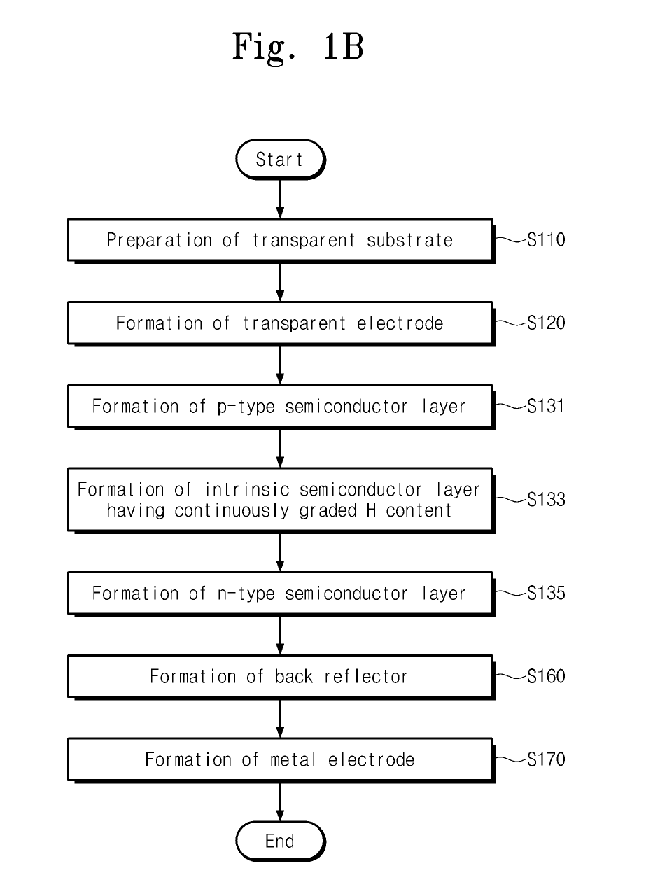

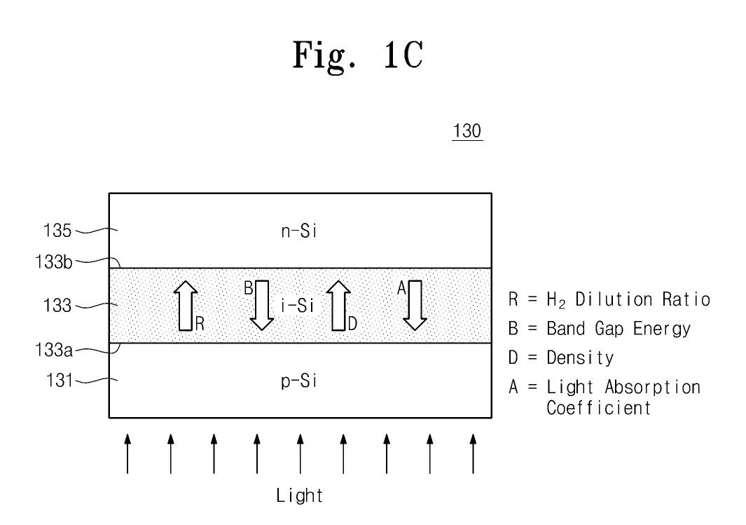

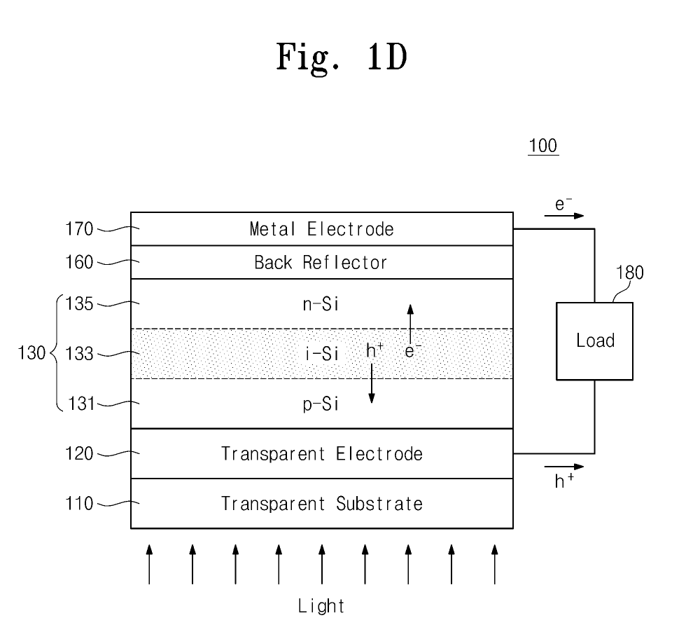

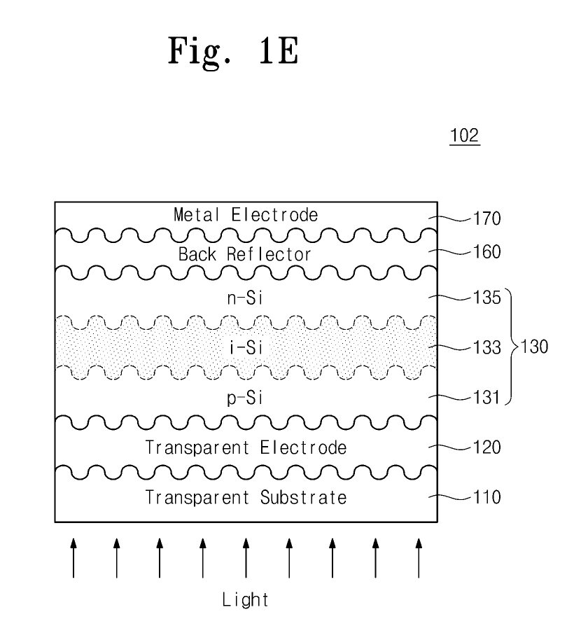

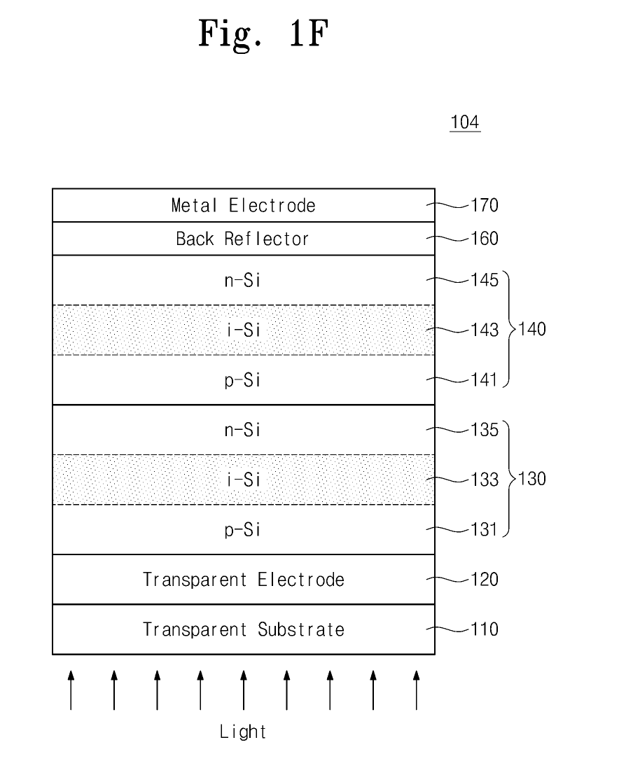

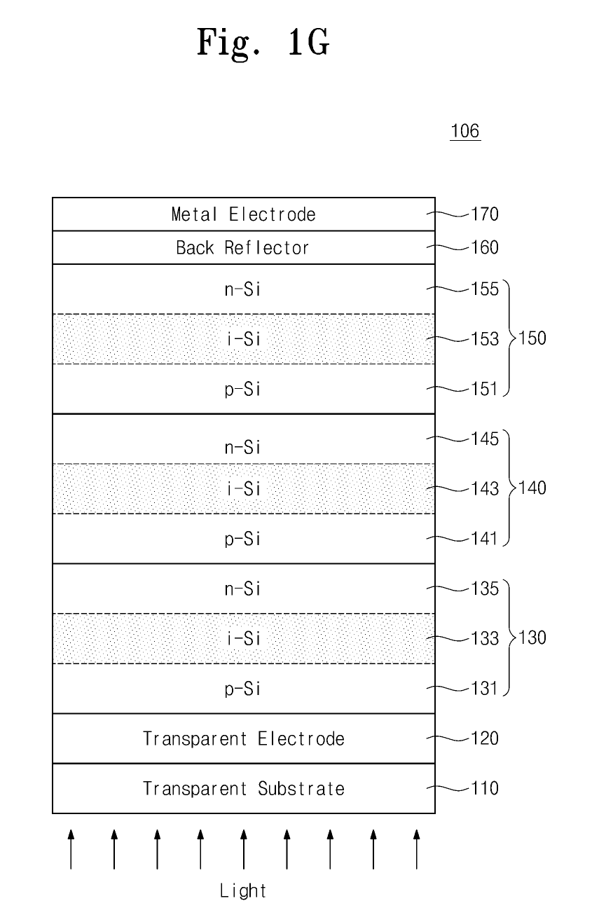

FIG. 1A is a sectional view of a thin-film solar cell according to example embodiments of the inventive concept, FIG. 1B is a flow chart illustrating a method of fabricating a thin-film solar cell according to example embodiments of the inventive concept, and FIG. 1C is a sectional view schematically illustrating a cell of a thin-film solar cell according to example embodiments of the inventive concept.

Referring to FIG. 1A, a thin-film solar cell 100 may be configured to have a single junction superstrate structure including a transparent electrode 120, a cell 130 of p-i-n structure, and a metal electrode 170 that are sequentially stacked in a form of thin film on a transparent substrate 110. In example embodiments, the cell 130 may be configured to have a pin diode structure. For example, the cell 130 may include a p-type semiconductor layer 131, an intrinsic semiconductor layer 133, and an n-type semiconductor layer 135 sequentially stacked on the transparent electrode 120. Alternatively, the cell 130 may include the n-type semiconductor layer 135, the intrinsic semiconductor layer 133, and the p-type semiconductor layer 131 sequentially stacked on the transparent electrode 120. A backside reflection layer or back reflector 160 may be further provided between the p-i-n cell 130 and the metal electrode 170. The thin-film solar cell 100 may be configured in such a way that a solar light may be incident into the transparent substrate 110.

Referring to FIG. 1B in conjunction with FIG. 1A, the transparent substrate 110 may be provided (S110), and then, the transparent electrode 120 serving as a front-side electrode may be formed on the transparent substrate 110 (S120). The transparent substrate 110 may be formed of an optically transparent material, such as glass, plastic or resin. The transparent electrode 120 may be formed of at least one transparent conductive oxide, such as, ZnO, ITO, or SnOx (x<2) doped with metal ions, to allow the solar light incident from the transparent substrate 110 to pass therethrough. For example, the transparent electrode 120 may be a layer of ZnO doped with Al, Ga, In, or B, or a layer of SnO doped with F, which may be formed using a sputtering or a metal organic chemical vapor deposition (MOCVD).

The p-type semiconductor layer 131 may be formed on the transparent electrode 120 (S131). The p-type semiconductor layer 131 may be formed of a p-type semiconductor layer (e.g., of a group IV element doped with a group 3B element, such as boron (B)), which may be formed using a physical vapor deposition (PVD) or a chemical vapor deposition (CVD). The PVD process may be performed in hydrogen ambient. The CVD process may be performed using one of a plasma-enhanced CVD, a hot-wall CVD, hot-wire CVD, an atmospheric pressure CVD, and so forth. Except for particulars mentioned, the word “deposition” or “deposition process” to be used in the specification may be one of various deposition techniques known in this technical field.

As one embodiment, the p-type semiconductor layer 131 may include a silicon layer. Alternatively, the p-type semiconductor layer 131 may include a layer of SiGe, SiC, SiO, SiN, SiON, SiCN, SiGeO, SiGeN, SiGeC, or any combination thereof. In example embodiments, the p-type semiconductor layer 131 may be a p-type silicon layer deposited by, for example, a PECVD using a silane (SiH₄) gas, a hydrogen (H₂) gas and p-type dopants (e.g., B₂H₆). The p-type semiconductor layer 131 may have a crystal structure of amorphous, single-crystalline, poly-crystalline, micro-crystalline, or nano-crystalline. In the specification, the word “semiconductor layer” may be a layer made of a semiconductor material and/or a semiconductor-containing layer.

The intrinsic semiconductor layer 133 may be formed on the p-type semiconductor layer 131 to serve as a light absorption layer (S133). As one embodiment, the intrinsic semiconductor layer 133 may be formed of a Si-containing material. Alternatively, the intrinsic semiconductor layer 133 may be formed by depositing a material of SiGe, SiC, SiO, SiN, SiON, SiCN, SiGeO, SiGeN, SiGeC, or any combination thereof. The intrinsic semiconductor layer 133 may have a crystal structure of amorphous, single-crystalline, poly-crystalline, micro-crystalline, nano-crystalline, or any mixture thereof. In example embodiments, the intrinsic semiconductor layer 133 may be formed of an amorphous silicon layer, not including the crystalline or micro-crystalline silicon layer.

The intrinsic semiconductor layer 133 may be formed to have a non-uniform property varying continuously along a thickness direction thereof. For example, the formation of the intrinsic semiconductor layer 133 may include depositing an intrinsic silicon layer on the p-type semiconductor layer 131 by a PECVD using a silicon precursor source gas, such as, SiH₄, Si₂H₆, SiH₂Cl₂, SiH₃Cl, SiHCl₃ or any combination thereof, in which hydrogen (H₂) gas is added. In example embodiments, a hydrogen ratio R, e.g., [H₂]/[SiH₄], may be gradually increased during the formation of the intrinsic semiconductor layer 133. The intrinsic semiconductor layer 133 may be all amorphous. In the hydrogen dilution ratio, [SiH₄] may be replaced by [SiH₄], [Si₂H₆], [SiH₂Cl₂], [SiH₃Cl], or [SiHCl₃]. In example embodiments, the hydrogen dilution ratio may range from about 1 to about 20, but example embodiments of the inventive concepts may not be limited thereto.

In example embodiments, as shown in FIG. 1C, the hydrogen dilution ratio R may increase from a light-incident surface, to which a solar light is incident, to an opposite surface opposite to the light-incident surface. In some embodiments, the hydrogen dilution ratio R may increase from a first interface 133a between the p-type semiconductor layer 131 and the intrinsic semiconductor layer 133 toward a second interface 133b between the n-type semiconductor layer 135 and the intrinsic semiconductor layer 133. In other words, the hydrogen dilution ratio R may increase continuously with increasing a distance from the transparent substrate 110, to which a solar light is incident, and/or increase continuously with decreasing a distance from the metal electrode 170. In the case in which the hydrogen dilution ratio R is gradually increased during the formation of the intrinsic semiconductor layer 133, hydrogen content in the intrinsic semiconductor layer 133 may decrease continuously from the first interface 133a toward the second interface 133b.

Due to the use of the above process condition, the intrinsic semiconductor layer 133 may be formed to contain hydrogen therein, and the hydrogen may be bonded with defects in the intrinsic semiconductor layer 133. As a result, it is possible to reduce defects at which electron-hole pairs are recombined. This may enable to increase efficiency in generating electricity. In addition, in the case in which the intrinsic semiconductor layer 133 is formed to have the continuously graded hydrogen content, there may be substantially no interfacial surface in the intrinsic semiconductor layer 133. As a result, it may be possible to suppress carriers from being captured at interface.

Other properties of the intrinsic semiconductor layer 133 may vary continuously, because of the continuous change in the hydrogen dilution ratio R. For example, since the presence of hydrogen gas dilutes the silicon precursor source gas, the intrinsic semiconductor layer 133 may have graded density and crystallinity. If the hydrogen dilution ratio R is high, the intrinsic silicon layer may be slowly deposited and silicon atoms therein may be more regularly arranged. As a result, the intrinsic silicon layer may have an increased density and crystallinity. For example, if the hydrogen dilution ratio R is high, the intrinsic semiconductor layer 133 may be formed to have a micro-crystalline or crystalline structure or a high-density amorphous structure. In example embodiments, the intrinsic semiconductor layer 133 may be formed to have the amorphous structure, before forming the micro-crystalline structure, although its density and/or crystallinity is increased due to a high hydrogen dilution ratio R. The intrinsic semiconductor layer 133 of amorphous structure may have a density increasing from the first interface 133a toward the second interface 133b. The intrinsic semiconductor layer 133 of amorphous structure may have a relatively high light absorption coefficient, compared with an intrinsic semiconductor layer of crystalline structure. This may enable to increase energy-converting efficiency. Light-induced degradation of light absorption layer can be reduced by increasing hydrogen dilution ration even though the phase of the film is still amorphous. By contrast, in the case in which the hydrogen dilution ratio R is decreased, the intrinsic semiconductor layer 133 may be formed to have an amorphous structure with reduced density.

The higher the hydrogen dilution ratio R, the less bandgap energy the intrinsic semiconductor layer 133 may have. By contrast, the smaller the hydrogen dilution ratio R, the higher bandgap energy the intrinsic semiconductor layer 133 may have. A content of hydrogen may be inversely proportional to the hydrogen dilution ratio, and thus, a high hydrogen dilution ratio may lead to a decrease in bandgap energy. This effect can be found from FIG. 1C, in which a value of property is configured to increase along a direction of arrow. For example, a density D of the intrinsic semiconductor layer 133 may increase with increasing the hydrogen dilution ratio R, while a bandgap energy B and a light absorption coefficient A may decrease with increasing the hydrogen dilution ratio R. A range of wavelength absorbed by the intrinsic semiconductor layer 133 may vary according to the bandgap energy thereof. According to example embodiments of inventive concepts, the intrinsic semiconductor layer 133 may be configured to have the continuously graded bandgap energy, the solar cell can be configured to convert a solar light into electricity in an enlarged wavelength range. Even though the intrinsic layer 133 maintains amorphous phase, the bandgap energy can be varied from approximately 2.0 eV to 1.5 eV by increasing hydrogen dilution ratio.

In the case in which the intrinsic semiconductor layer 133 is formed on a layer, to which a solar light is incident, (e.g., the p-type semiconductor layer 131) by depositing an intrinsic silicon layer, by using the gradually increasing hydrogen dilution ratio as the afore-described embodiment, it may be possible to form the intrinsic semiconductor layer 133 having continuously graded properties. As a result, it may be possible to realize a solar cell having high conversion efficiency. For example, the conversion efficiency may be about 9.8% in the example embodiments but 9% in the case of a fixed hydrogen dilution ratio as in the conventional method. The conversion efficiency was measured from a single-junction amorphous-Si thin-film solar cell 100, in which the p-Si layer 131, the intrinsic amorphous Si layer 133 with the continuously graded hydrogen content, and the n-Si layer 135 were stacked, and in which a hydrogen content of the i-Si layer 133 was greater near the first interface 133a between the p-Si layer 131 and the i-Si layer 133 than that near the second interface 133b between the i-Si layer 133 and the n-Si layer 135. In example embodiments, properties of the solar cell may be strongly dependent on a changing direction of the hydrogen content. For example, if the hydrogen content of the i-Si layer 133 adjacent to the first interface 133a is smaller than that adjacent to the second interface 133b, the conversion efficiency was about 5.8%.

Referring back to FIGS. 1A and 1B, the n-type semiconductor layer 135 may be formed on the intrinsic semiconductor layer 133 (S135). The n-type semiconductor layer 135 may be formed of an n-type semiconductor layer (e.g., of a group IV element doped with a group 5B element, such as phosphorus (P)), which may be formed using a thin film deposition process. As one embodiment, the n-type semiconductor layer 135 may include a silicon layer doped with n-type dopant. Alternatively, the n-type semiconductor layer 135 may include a layer of SiGe, SiC, SiO, SiN, SiON, SiCN, SiGeO, SiGeN, SiGeC, or any combination thereof. In example embodiments, the n-type semiconductor layer 135 may be a n-type silicon layer deposited by, for example, a PECVD using a silane (SiH₄) gas, a hydrogen (H₂) gas and n-type dopants precursor gas (e.g., PH₃). The n-type semiconductor layer 135 may have a structure of amorphous, single-crystalline, poly-crystalline, micro-crystalline, or nano-crystalline. As described above, the cell 130 may be formed to have the p-type semiconductor layer 131, the intrinsic semiconductor layer 133, and the n-type semiconductor layer 135 sequentially stacked on the transparent electrode 120, thereby forming a p-i-n diode structure.

The backside reflection layer 160 may be formed on the n-type semiconductor layer 135 (S160). The backside reflection layer 160 may be configured to reduce a reflection loss of the solar light and increase a light trapping effect, thereby improving efficiency of the solar cell 100. The backside reflection layer 160 may be formed by depositing at least one of materials (e.g., ZnO, ZnO:Al, ZnO:Ga, ZnO:In, ZnO:B, and ZnO-containing films) exemplified for the transparent electrode 120 using a sputtering, a CVD, or E-beam evaporation.

The metal electrode 170 may be formed on the backside reflection layer 160 to serve as a backside electrode (S170). The metal electrode 170 may be formed to have a single-layered or multi-layered structure of transparent or opaque materials. In example embodiments, the metal electrode 170 may be formed by depositing at least one of Al, Ag, Cu, ZnO/Ag, ZnO/Al, and Ni/Al. The thin-film solar cell 100 of FIG. 1A may be formed by the afore-described process.

### Operating Principle

FIG. 1D is a sectional view illustrating an operating principle of a thin-film solar cell according to example embodiments of the inventive concept.

Referring to FIG. 1D, a solar light may be incident to the transparent substrate 110 and be absorbed in the intrinsic semiconductor layer 133 to generate electron and holes. The intrinsic semiconductor layer 133 may be depleted by the p-type semiconductor layer 131 and the n-type semiconductor layer 135, such that an electric field may be generated therein. Electrons (e⁻) and holes (h⁺) generated in the intrinsic semiconductor layer 133 may be drifted toward the n-type semiconductor layer 135 and the p-type semiconductor layer 131, respectively, due to the presence of an internal electric field. As a result, holes (h⁺) may be accumulated in the p-type semiconductor layer 131 and electrons (e⁻) may be accumulated in the n-type semiconductor layer 135, and thus, a photoelectron-motive force (photovoltage) may be produced between the p-type semiconductor layer 131 and the n-type semiconductor layer 135. Therefore, an electric current can be flowed, if the transparent electrode 120 is connected to the metal electrode 170 via a load 180.

### Modifications

FIGS. 1E through 1G are sectional views of thin-film solar cells according to other example embodiments of the inventive concept.

Referring to FIG. 1E, a thin-film solar cell 102 may include the transparent electrode 120 with a textured surface. The textured surface may enable to reduce reflection of an incident light and increase absorption of the incident light. The textured surface may be formed during the deposition of the transparent electrode 120 or by an etching process performed after the deposition. In example embodiments, at least one of the cell 130, the backside reflection layer 160 and the metal electrode 170 may be also provided to have such textured surface.

Referring to FIG. 1F, a thin-film solar cell 104 may be configured to have a double junction superstrate structure. In example embodiments, the thin-film solar cell 104 may further include a second cell 140 of p-i-n structure stacked on the first cell 130 of p-i-n structure. The first cell 130 may be configured to have the substantially same structure as that of FIG. 1A.

The second cell 140 may be formed by sequentially depositing a second p-type semiconductor layer 141, a second intrinsic semiconductor layer 143, and a second n-type semiconductor layer 145 on the first n-type semiconductor layer 135. The second p-type semiconductor layer 141 may be configured to have the substantially identical or analogous to the first p-type semiconductor layer 131, and the second n-type semiconductor layer 145 may be configured to have the substantially identical or analogous to the first n-type semiconductor layer 135. The second intrinsic semiconductor layer 143 may be configured to have the substantially identical or analogous to the first intrinsic semiconductor layer 133. For example, the second intrinsic semiconductor layer 143 may be an amorphous layer, which may be formed using the substantially same process condition as that for the first intrinsic semiconductor layer 133, in terms of hydrogen dilution ratio.

Alternatively, the second intrinsic semiconductor layer 143 may be an amorphous layer, like the first intrinsic semiconductor layer 133, but it may be formed using different process condition in the hydrogen dilution ratio. For example, the first intrinsic semiconductor layer 133 may have a hydrogen dilution ratio ranging from 1 to 10, while the second intrinsic semiconductor layer 143 may have a hydrogen dilution ratio ranging from 10 to 20. Due to the difference in the hydrogen dilution ratio, one of the first and second intrinsic semiconductor layers 133 and 143 may be a low density amorphous layer, and the other may be a high density amorphous layer. In example embodiments, the hydrogen dilution ratio during deposition process may be configured to increase along an incident direction of the solar light. But example embodiments of the inventive concepts may not be limited to the exemplified values of the hydrogen dilution ratio.

In other example embodiments, one of the first and second intrinsic semiconductor layers 133 and 143 may be an amorphous layer, and the other may be a crystalline layer (e.g., of single-, poly-, micro-crystalline, or amorphous-nanocrystalline mixed structure). In still other example embodiments, the first intrinsic semiconductor layer 133 may be an amorphous layer, and the second intrinsic layer 143 may have a mixed structure which comprises a crystalline layer and an amorphous layer.

Referring to FIG. 1G, a thin-film solar cell 106 may be configured to have a triple junction superstrate structure. For example, the thin-film solar cell 106 may further include second and third cells 140 and 150 of p-i-n structure stacked on the first cell 130 of p-i-n structure. The first cell 130 may be configured to have the substantially same structure as that of FIG. 1A.

The second cell 140 may be formed by sequentially depositing a second p-type semiconductor layer 141, a second intrinsic semiconductor layer 143, and a second n-type semiconductor layer 145 on the first n-type semiconductor layer 135. The second p-type semiconductor layer 141 may be configured to have the substantially identical or analogous to the first p-type semiconductor layer 131, and the second n-type semiconductor layer 145 may be configured to have the substantially identical or analogous to the first n-type semiconductor layer 135.

The third cell 150 may be formed by sequentially depositing a third p-type semiconductor layer 151, a third intrinsic semiconductor layer 153 and a third n-type semiconductor layer 155 on the second n-type semiconductor layer 145. In example embodiments, the third cell 150 may be configured to have the substantially identical or analogous to the first cell 130 and/or the second cell 140. The third p-type semiconductor layer 151 may be configured to have the substantially identical or analogous to one or both of the first and second p-type semiconductor layers 131 and 141, and the third n-type semiconductor layer 155 may be configured to have the substantially identical or analogous to one or both of the first and second n-type semiconductor layers 135 and 145. The third intrinsic semiconductor layer 153 may be configured to have the substantially identical or analogous to one or both of the first and second intrinsic semiconductor layers 133 and 143.

Alternatively, the third intrinsic semiconductor layer 153 may be an amorphous layer, like the first and second intrinsic semiconductor layers 133 and 143, but it may be formed using different process condition in the hydrogen dilution ratio. For example, the first intrinsic semiconductor layer 133 may have a hydrogen dilution ratio ranging from 1 to 7, the second intrinsic semiconductor layer 143 may have a hydrogen dilution ratio ranging from 7 to 15, and the third intrinsic semiconductor layer 153 may have a hydrogen dilution ratio ranging from 15 to 20. In other embodiments, one of the first and third intrinsic semiconductor layers 133 and 153 may have a hydrogen dilution ratio ranging from 7 to 15, and the other may have a hydrogen dilution ratio ranging from 15 to 20, and the second intrinsic semiconductor layer 133 may have a hydrogen dilution ratio ranging from 1 to 7. In still other embodiments, one of the first and third intrinsic semiconductor layers 133 and 153 may have a hydrogen dilution ratio ranging from 1 to 7, and the other may have a hydrogen dilution ratio ranging from 7 to 15, and the second intrinsic semiconductor layer 133 may have a hydrogen dilution ratio ranging from 15 to 20. In other example embodiments, at least one of the first, the second, and the third intrinsic layers 133, 143 and 153 may be formed in the process condition with continuously changing hydrogen dilution ratio. In example embodiments, the hydrogen dilution ratio may be configured to increase along an incident direction of the solar light.

In other example embodiments, at least one of the first, second and third intrinsic semiconductor layers 133, 143 and 153 may be an amorphous layer, and the others may be a crystalline layer. In still other example embodiments, at least one of the first, second and third intrinsic semiconductor layers 133, 143 and 153 may be an amorphous layer, and the others may have a mixed layer which comprises a crystalline layer and an amorphous layer are mixed.

### Embodiment 2

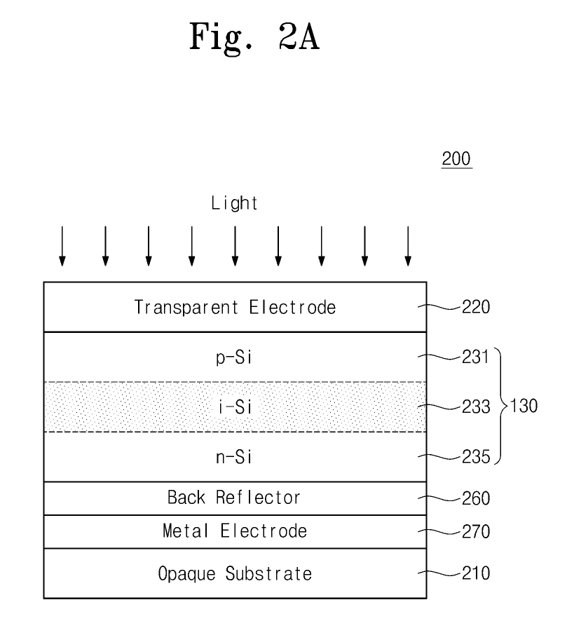

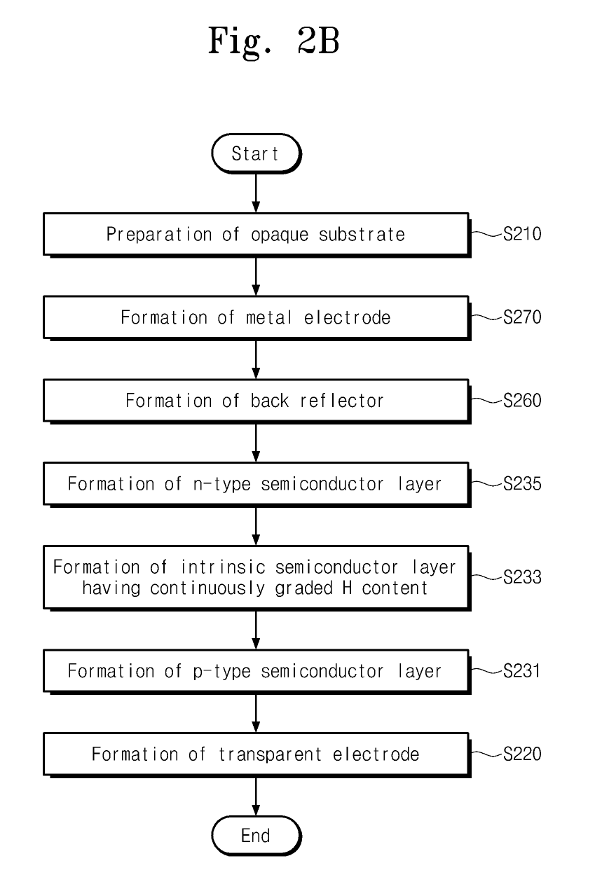

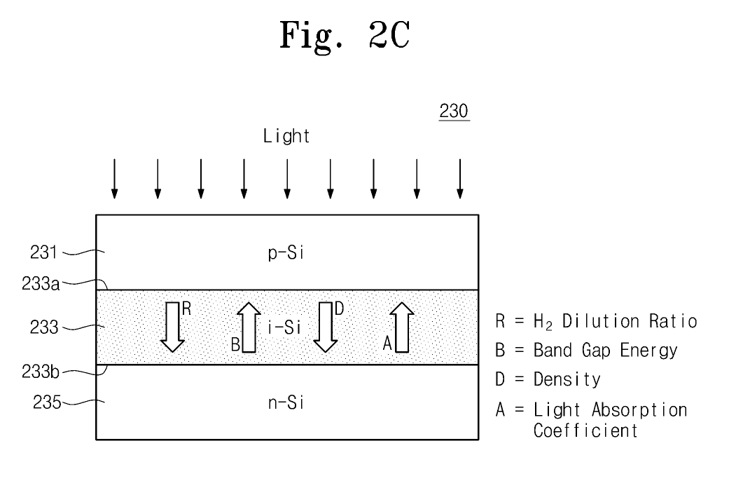

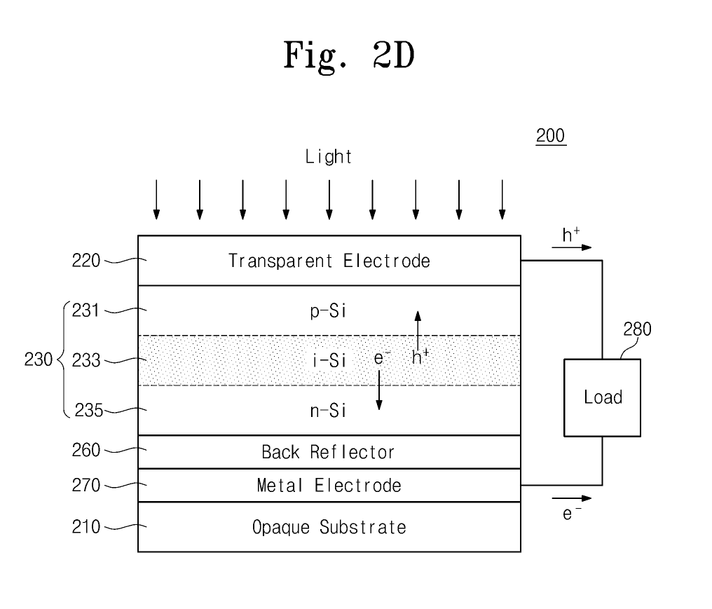

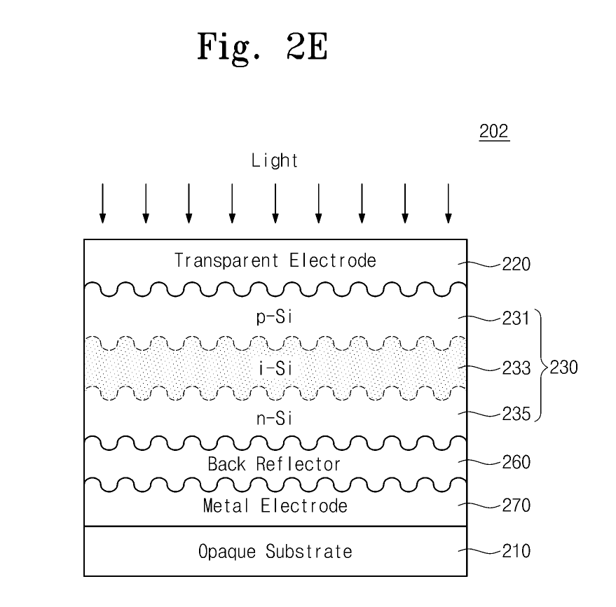

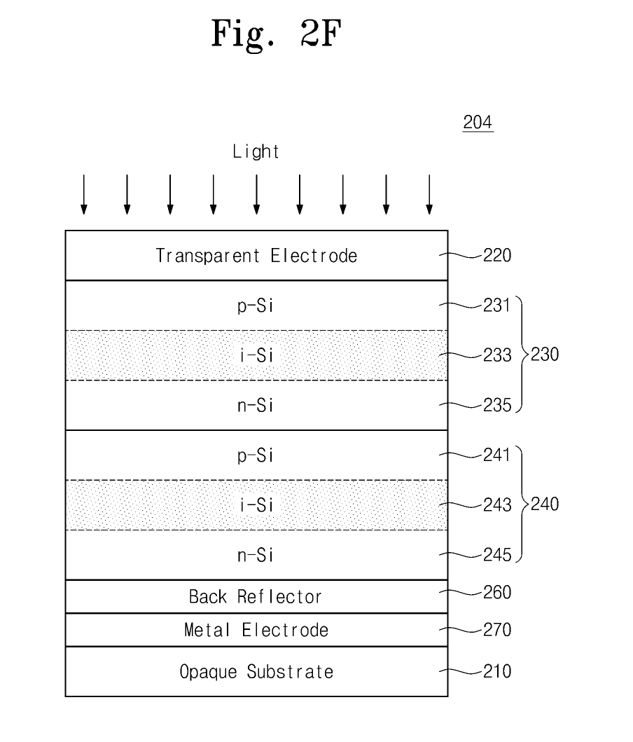

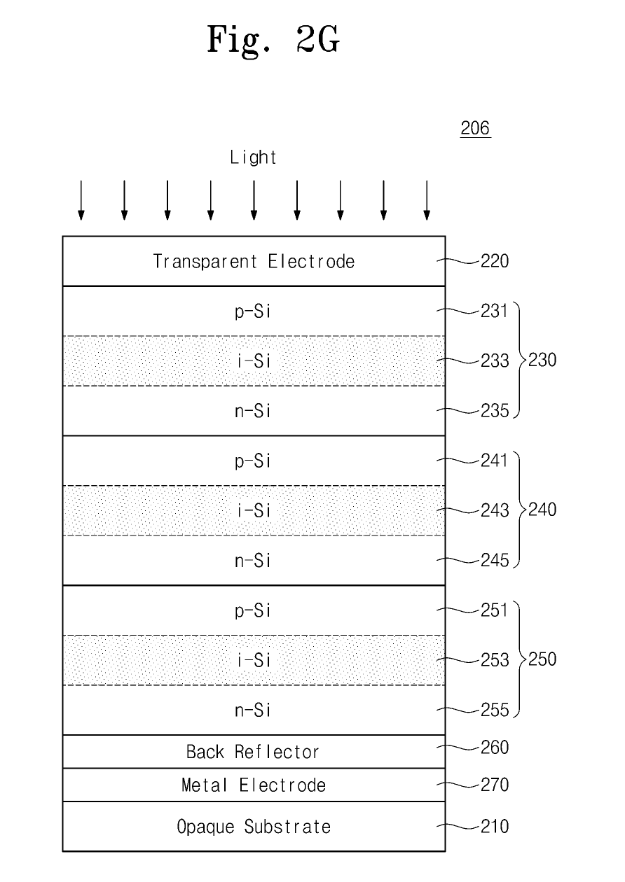

FIG. 2A is a sectional view of a thin-film solar cell according to modified embodiments of the inventive concept, FIG. 2B is a flow chart illustrating a method of fabricating a thin-film solar cell according to modified embodiments of the inventive concept, and FIG. 2C is a sectional view illustrating a cell of a thin-film solar cell according to modified embodiments of the inventive concept.

Referring to FIG. 2A, a thin-film solar cell 200 may be configured to have a single junction substrate structure including a metal electrode 270, a cell 230 of n-i-p structure, and a transparent electrode 220 that are sequentially stacked in a form of thin film on an opaque substrate 210. In example embodiments, the cell 230 may include an n-type semiconductor layer 235, an intrinsic semiconductor layer 233, and a p-type semiconductor layer 231 sequentially stacked on the metal electrode 270. In other embodiments, the cell 230 may include a p-type semiconductor layer 231, an intrinsic semiconductor layer 233, and an n-type semiconductor layer 235 sequentially stacked on the metal electrode 270. A backside reflection layer 260 may be provided between the metal electrode 270 and the cell 230. The thin-film solar cell 200 may be configured in such a way that a solar light may be incident into the transparent electrode 220.

Referring to FIG. 2B in conjunction with FIG. 2A, the opaque substrate 210 may be provided (S210), and the metal electrode 270 serving as a backside electrode may be formed on the opaque substrate 210 (S270). The metal electrode 270 may be formed to have a single-layered or multi-layered structure of transparent or opaque materials, such as Al, Ag, Cu, ZnO/Ag, ZnO/Al, or Ni/Al.

The backside reflection layer 260 may be formed on the metal electrode 270 (S260). In example embodiments, since a solar light is incident to the transparent electrode 220, the thin-film solar cell 200 may be configured to include the opaque substrate 210 formed of an opaque metal material. In other embodiments, a transparent substrate (e.g., as the embodiments described with reference to FIG. 1A) may be used instead of the opaque substrate 210. The backside reflection layer 260 may be formed of the same material (e.g., ZnO:Al, ZnO:Ga, ZnO:In, ZnO:B, and ZnO-containing materials) as at least one of those exemplified for the transparent electrode 120.

The n-type semiconductor layer 235 may be formed on the metal electrode 270 (S235), an intrinsic semiconductor layer 233 may be formed on the n-type semiconductor layer 235 (S233), and a p-type semiconductor layer 231 may be formed on the intrinsic semiconductor layer 233 (S231). In other words, the cell 230 may be formed to have an n-i-p structure. The n-type and p-type semiconductor layers 235 and 231 may be formed to have the identical or analogous to those of the n-type and p-type semiconductor layers 135 and 131 of FIG. 1A. For example, one of the n-type and p-type semiconductor layers 235 and 231 may be a layer including Si, SiGe, SiC, SiO, SiN, SiON, SiCN, SiGeO, SiGeN, SiGeC, or any combination thereof and have one of amorphous, single-crystalline, poly-crystalline, micro-crystalline, or amorphous-nanocrystalline mixed structure.

Similar to the intrinsic semiconductor layer 133 of FIG. 1A, the intrinsic semiconductor layer 233 may be formed to have a non-uniform property continuously varying along a thickness direction thereof. For example, the intrinsic semiconductor layer 233 may be formed to have a hydrogen dilution ratio gradually increasing along an incident direction of the solar light (e.g., increasing with increasing a distance from a surface, to which the solar light is incident). In example embodiments, the formation of the intrinsic semiconductor layer 233 may include the deposition of an intrinsic silicon layer on the n-type semiconductor layer 235 by a PECVD using a silicon precursor source gas, such as, SiH₄, Si₂H₆, SiH₂Cl₂, SiH₃Cl, SiHCl₃ or any combination thereof, in which a hydrogen gas (H₂) is added. Alternatively, the intrinsic semiconductor layer 233 may include a layer of SiGe, SiC, SiO, SiN, SiON, SiCN, SiGeO, SiGeN, SiGeC, or any combination thereof. In example embodiments, the intrinsic semiconductor layer 233 may be formed by gradually decreasing a hydrogen dilution ratio. As shown in FIG. 2C, in the intrinsic semiconductor layer 233, the hydrogen dilution ratio R may increase along an incident direction of the solar light, and the hydrogen content may decrease along the incident direction of the solar light. In other words, the hydrogen dilution ratio R may increase in a continuous manner from the first interface 233a toward the second interface 233b, and this may enable to prevent a distinct interface from being formed in the intrinsic semiconductor layer 233. In addition, the hydrogen content may decrease in a continuous manner from the first interface 233a toward the second interface 233b. For example, the hydrogen dilution ratio R may range from 1 to 20, but example embodiments of the inventive concepts may not be limited thereto. That is, the hydrogen dilution ratio R may increase in a continuous manner with increasing a distance from the transparent electrode 220, to which a solar light is incident, and/or with decreasing a distance from the opaque substrate 210. In the intrinsic semiconductor layer 233, a bandgap energy B and a light absorption coefficient A may decrease in a gradual manner from the first interface 233a toward the second interface 233b, while a density D may increase, in addition to the gradual change of the hydrogen dilution ratio R.

Referring back to FIGS. 2A and 2B, the transparent electrode 220 serving as a front-side electrode may be formed on the p-type semiconductor layer 231 (S220). The transparent electrode 220 may be formed of at least one transparent conductive oxide (TCO), such as, ZnO, ITO, or SnOx (x<2) doped with metal ions, to allow the incident solar light to pass therethrough. For example, the transparent electrode 220 may be a layer of ZnO doped with Al, Ga, In, or B, or a layer of SnO doped with F, which may be formed using a sputtering or a MOCVD. The thin-film solar cell 200 of FIG. 2A may be formed by the afore-described process.

### Operating Principle

FIG. 2D is a sectional view illustrating an operating principle of a thin-film solar cell according to modified embodiments of the inventive concept.

Referring to FIG. 2D, a solar light may be incident to the transparent electrode 220 and be absorbed in the intrinsic semiconductor layer 233 to generate electrons and holes. Electrons (e⁻) and holes (h⁺) in the intrinsic semiconductor layer 233 may be drifted toward and accumulated in the n-type semiconductor layer 235 and the p-type semiconductor layer 231, respectively, due to the presence of an internal electric field. As a result, a photoelectron-motive force (photovoltage) may be produced between the p-type semiconductor layer 231 and the n-type semiconductor layer 235. Thus, an electric current can be flowed, if the transparent electrode 220 is connected to the metal electrode 270 via a load 280.

### Modifications

FIGS. 2E through 2G are sectional views of thin-film solar cells according to still other example embodiments of the inventive concept.

Referring to FIG. 2E, a thin-film solar cell 202 may include a textured structure. In example embodiments, at least one of the transparent electrode 220, the cell 230, the backside reflection layer 260, and the metal electrode 270 may be configured to have such textured surface.

Referring to FIG. 2F, a thin-film solar cell 204 may be configured to have a double junction substrate structure. In example embodiments, the thin-film solar cell 204 may further include a second cell 240 of n-i-p structure between the first cell 230 of n-i-p structure and the metal electrode 270. The first cell 230 may be configured to have the substantially identical or analogous to that of FIG. 2A. The second cell 240 may be formed by sequentially depositing a second n-type semiconductor layer 245, a second intrinsic semiconductor layer 243, and a second p-type semiconductor layer 241 on the metal electrode 270. The second p-type semiconductor layer 241 may be configured to have the substantially identical or analogous to the first p-type semiconductor layer 231, and the second n-type semiconductor layer 245 may be configured to have the substantially identical or analogous to the first n-type semiconductor layer 235.

The second intrinsic semiconductor layer 243 may be configured to have the substantially identical or analogous to the first intrinsic semiconductor layer 233. However, in example embodiments, the second intrinsic semiconductor layer 243 may be configured to have technical features different from the first intrinsic semiconductor layer 233. For example, a hydrogen dilution ratio of the second intrinsic semiconductor layer 233 may be either equivalent to, greater than or smaller than that of the second intrinsic semiconductor layer 243. Alternatively, one of the first and second intrinsic semiconductor layers 233 and 243 may be an amorphous layer, and the other may be a crystalline layer (e.g., of single-, poly-, or micro-crystalline structure) or have a mixed layer which comprises a crystalline layer and an amorphous layer.

Referring to FIG. 2G, a thin-film solar cell 206 may be configured to have a triple junction substrate structure. For example, the thin-film solar cell 206 may further include second and third cells 240 and 250 of n-i-p structure between the first cell 230 of n-i-p structure and the metal electrode 270. The third cell 250 may be formed by sequentially depositing a third n-type semiconductor layer 255, a third intrinsic semiconductor layer 253, and a third p-type semiconductor layer 251 on the metal electrode 270. In example embodiments, the third cell 250 may be configured to have the substantially identical or analogous to the first cell 230 and/or the second cell 240.

In example embodiments, the first, second and third intrinsic semiconductor layers 233, 243 and 253 may be equivalent to or different from each other in terms of hydrogen dilution ratio. In example embodiments, the first, second and third intrinsic semiconductor layers 233, 243 and 253 may be amorphous layers, whose hydrogen dilution ratios increase or decrease according to the order in which they are stacked. In other example embodiments, the first, second and third intrinsic semiconductor layers 233, 243 and 253 may be amorphous layers, whose hydrogen dilution ratios increase initially and then decrease, or decrease initially and then increase according to the order in which they are stacked. In other example embodiments, at least one of the first, the second, and the third intrinsic layers 233, 243 and 253 may be formed in the process condition with continuously changing hydrogen dilution ratio and may have amorphous structure.

In other example embodiments, at least one of the first, second and third intrinsic semiconductor layers 233, 243 and 253 may be an amorphous layer, and the others may be a crystalline layer or a mixed layer which comprises a crystalline layer and an amorphous layer are mixed.

According to example embodiments of the inventive concept, an intrinsic semiconductor layer is formed to have a continuously, but not abruptly, varying property. This enables to increase energy conversion efficiency of the solar cell. In addition, the continuously varying property of the intrinsic semiconductor layer can be realized without using an additional process or apparatus. This enables to realize the solar cell without an increase in fabrication cost. Furthermore, an amorphous structure may be used for the intrinsic semiconductor layer, and this enables to increase optical absorption coefficient, compared with the case of a crystalline structure. As a result, it is possible to increase conversion efficiency of the solar cell.

While example embodiments of the inventive concepts have been particularly shown and described, it will be understood by one of ordinary skill in the art that variations in form and detail may be made therein without departing from the spirit and scope of the attached claims.

What is claimed is:

1. A thin-film solar cell, comprising:
a substrate; and
a cell comprising an amorphous layer disposed on the substrate, the amorphous layer including an intrinsic semiconductor with a continuously graded hydrogen content,
wherein the amorphous layer comprises an incident surface to which a light is incident and an opposite surface, and
wherein the hydrogen content gradually decreases from the incident surface toward the opposite surface.

2. The solar cell of claim 1, wherein the substrate comprises a transparent substrate disposed adjacent to the incident surface, and the hydrogen content gradually decreases with increasing a distance from the transparent substrate.

3. The solar cell of claim 2, wherein the cell comprises:
a p-type semiconductor layer disposed on the transparent substrate;
the amorphous layer having the continuously graded hydrogen content disposed on the p-type semiconductor layer; and
an n-type semiconductor layer disposed on the amorphous layer,
wherein the hydrogen content gradually decreases from a first interface between the amorphous layer and the p-type semiconductor layer toward a second interface between the amorphous layer and the n-type semiconductor layer.

4. The solar cell of claim 3, further comprising:
a transparent electrode disposed between the transparent substrate and the cell; and
a metal electrode disposed on the cell.

5. The solar cell of claim 1, wherein the substrate comprises an opaque substrate disposed adjacent to the opposite surface, and the hydrogen content gradually decreases with decreasing a distance from the opaque substrate.

6. The solar cell of claim 5, wherein the cell comprises:
an n-type semiconductor layer disposed on the opaque substrate;
the amorphous layer having the continuously graded hydrogen content disposed on the n-type semiconductor layer; and
a p-type semiconductor layer disposed on the amorphous layer,
wherein the hydrogen content gradually decreases from a first interface between the amorphous layer and the p-type semiconductor layer toward a second interface between the amorphous layer and the n-type semiconductor layer.

7. The solar cell of claim 6, further comprising:
a metal electrode disposed between the opaque substrate and the cell; and
a transparent electrode disposed on the cell to allow the light to be incident thereto.

8. The solar cell of claim 1, wherein a bandgap energy and a light absorption coefficient of the amorphous layer continuously decrease from the incident surface toward the opposite surface, and a density of the amorphous layer continuously increases from the incident surface toward the opposite surface.

9. The solar cell of claim 1, wherein the intrinsic semiconductor includes silicon.

10. The solar cell of claim 1, wherein the amorphous layer comprises one of Si, SiGe, SiC, SiO, SiN, SiON, SiCN, SiGeO, SiGeN, SiGeC and any combination thereof.

11. A thin-film solar cell, comprising:
a substrate;
a first cell disposed on the substrate, the first cell comprising a first n-type semiconductor layer, a first p-type semiconductor layer, and a first amorphous layer comprising intrinsic semiconductor with a continuously graded hydrogen content interposed between the first n-type semiconductor layer and the first p-type semiconductor layer;
a metal electrode adjacent to the first n-type semiconductor layer; and
a transparent electrode adjacent to the first p-type semiconductor layer,
wherein the hydrogen content of the first amorphous layer gradually decreases from a first interface, to which a light is incident, toward a second interface opposite to the first interface, and the first and second interfaces are two opposite surfaces of the first amorphous layer being in contact with the first p-type semiconductor layer and the first n-type semiconductor layer, respectively.

12. The solar cell of claim 11, wherein the substrate comprises a transparent substrate, to which a light is incident, and
the transparent electrode, the first p-type semiconductor layer, the first amorphous layer, the first n-type semiconductor layer, and the metal electrode are sequentially stacked on the transparent substrate.

13. The solar cell of claim 12, further comprising at least one second cell interposed between the first cell and the metal electrode,
wherein the second cell comprises a second p-type semiconductor layer, a second intrinsic semiconductor layer with a continuously graded hydrogen content, and a second n-type semiconductor layer sequentially stacked on the first n-type semiconductor layer,
the second intrinsic semiconductor layer comprises at least one of an intrinsic amorphous silicon layer and an intrinsic crystalline silicon layer, and
the hydrogen content of the second intrinsic semiconductor layer gradually decreases with increasing a distance from the transparent substrate.

14. The solar cell of claim 11, wherein the substrate comprises an opaque substrate, and the metal electrode, the first n-type semiconductor layer, the first amorphous layer, the first p-type semiconductor layer, and the transparent electrode are sequentially stacked on the opaque substrate, wherein a light is incident to the transparent electrode.

15. The solar cell of claim 14, further comprising at least one second cell interposed between the first cell and the metal electrode,
wherein the second cell comprises a second n-type semiconductor layer, a second intrinsic semiconductor layer with a continuously graded hydrogen content, and a second p-type semiconductor layer sequentially stacked on the metal electrode,
the second intrinsic semiconductor layer comprises at least one of an intrinsic amorphous silicon layer, an intrinsic microcrystalline silicon layer and an intrinsic crystalline silicon layer, and
the hydrogen content of the second intrinsic semiconductor layer gradually decreases with decreasing a distance from the opaque substrate.

16. The solar cell of claim 11, wherein the first amorphous layer comprises one of Si, SiGe, SiC, SiO, SiN, SiON, SiCN, SiGeO, SiGeN, SiGeC and any combination thereof.

17. A method of fabricating a thin-film solar cell, comprising:
providing a substrate;
forming an cell including a p-type semiconductor layer disposed on the substrate, an n-type semiconductor layer, and an amorphous layer including an intrinsic semiconductor layer with a continuously graded hydrogen content interposed between the p-type and n-type semiconductor layers;
forming a transparent electrode adjacent to the p-type semiconductor layer; and
forming a metal electrode adjacent to the n-type semiconductor layer,
wherein the amorphous layer has an incident surface, to which a light is incident, and an opposite surface, and
the hydrogen content gradually decreases from the incident surface toward the opposite surface.

18. The method of claim 17, wherein the amorphous layer comprises one of Si, SiGe, SiC, SiO, SiN, SiON, SiCN, SiGeO, SiGeN, SiGeC and any combination thereof.

19. The method of claim 18, wherein the substrate comprises a transparent substrate disposed adjacent to the incident surface,
wherein the forming of the cell comprises:
forming the p-type semiconductor layer on the transparent substrate;
forming the amorphous layer on the p-type semiconductor layer by supplying using a gas mixture of a semiconductor precursor source gas diluted with hydrogen gas, a hydrogen dilution ratio being gradually increased as the forming of the amorphous layer advances; and
forming the n-type semiconductor layer on the amorphous layer.

20. The method of claim 18, wherein the substrate comprises an opaque substrate disposed adjacent to the opposite surface,
wherein the forming of the cell comprises:
forming the n-type semiconductor layer on the opaque substrate;
forming the amorphous layer on the n-type semiconductor layer by supplying using a gas mixture of a semiconductor precursor source gas diluted with hydrogen gas, a hydrogen dilution ratio being gradually decreased as the forming of the amorphous layer advances; and
forming the p-type semiconductor layer on the amorphous layer.
